(19) United States
(12) Patent Application Publication
(10) Pub. No.: US 2012/0160550 A1
(43) Pub. Date: Jun. 28, 2012

(54) PRINTED CIRCUIT BOARD HAVING EMBEDDED ELECTRONIC COMPONENT AND METHOD OF MANUFACTURING THE SAME

(75) Inventors: Tae Sung JEONG, Gyunggi-do (KR); Doo Hwan LEE, Gyunggi-do (KR); Seung Eun LEE, Gyunggi-do (KR)

(73) Assignee: SAMSUNG ELECTRO-MECHANICS CO., LTD., Gyunggi-do (KR)

(21) Appl. No.: 13/252,777

(22) Filed: Oct. 4, 2011

(30) Foreign Application Priority Data
Dec. 22, 2010 (KR) 10-2010-0132715

(51) Int. Cl. H05K 1/09; H05K 1/16; H05K 1/02; H05K 3/30

(52) U.S. Cl. 174/257; 29/832; 174/260; 174/258

(57) ABSTRACT

Disclosed is a printed circuit board having an embedded electronic component, which includes a first insulating layer, an electronic component disposed in an opening formed in a thickness direction of the first insulating layer and having a metal bump, a polymer layer formed on one side of the first insulating layer and on which the electronic component is seated so that the metal bump of the electronic component perforates the polymer layer, a second insulating layer formed on the other side of the first insulating layer so as to embed the electronic component, a first circuit layer formed on the second insulating layer, and a second circuit layer formed on the polymer layer so as to be directly electrically connected to the metal bump that perforates the polymer layer, and in which roughness is formed on the polymer layer so that the force of adhesion of the polymer layer to a plating layer is enhanced, thus ensuring reliability of the electrical connection of a circuit layer which is subsequently formed.

### CROSS REFERENCE TO RELATED APPLICATION

This application claims the benefit of Korean Patent Application No. 10-2010-0132715, filed Dec. 22, 2010, entitled “A printed circuit board comprising embedded electronic component within and a method for manufacturing,” which is hereby incorporated by reference in its entirety into this application.

### BACKGROUND OF THE INVENTION

1. Technical Field

The present invention relates to a printed circuit board (PCB) having an embedded electronic component and a method of manufacturing the same.

2. Description of the Related Art

Typically circuit boards include a variety of active and passive elements such as resistors, capacitors, inductors, transformers, filters, mechanical switches, relays and so on. On the other hand, electronic devices are configured such that respective elements are systematically connected so that they can efficiently perform their original functions. Thus, when power is applied to circuits, various passive or active elements of the electronic devices carry out their functions.

In particular, the market trend calling for semiconductor packages having a reduced profile and a variety of functions requires that a variety of techniques be used to fabricate PCBs. Recently the development of embedded PCBs is receiving attention as a kind of next-generation multifunctional and small packaging technology. The embedded PCB is manufactured by inserting three passive elements that are fundamentally required when constituting an electronic circuit, for example, a capacitor (C), a resistor (R) and an inductor (L), which have been conventionally mounted on the surface of a substrate, into a PCB so that their functions are executed in the PCB, advantageously reducing the area of passive elements on the surface of the substrate. Furthermore, reducing the size of the PCB is expected to increase the efficiency of products and decrease the PCB price, and also, shortening the length of the connection between active and passive elements may decrease the number of inductance components, thus improving electrical performance. Moreover, because the number of solder bonds may be lowered, PCB mounting reliability may be improved.

Also, the embedded PCB in which elements are mounted in a PCB in accordance with the demands for multi-functionality and miniaturization is highly functionalized to some degree. For instance, the distance of the wiring may be minimized at a high frequency of 100 MHz or more, and the problems of reliability resulting from connecting components using wire bonding or solder balls used in flip chip or BGA (Ball Grid Array) may be solved, as needed. Also, the embedded PCB may make great contributions to the environmental field because there is no need for soldering.

However, conventional embedded PCBs and manufacturing methods thereof are disadvantageous because vias are used to form electrical connections with electronic components (elements), which undesirably increases the processing cost and complicates the manufacturing process, and also because low peel strength between the insulating layer and the plating layer upon forming the plating layer on the insulating layer may weaken the force of adhesion, undesirably decreasing reliability of electrical connection of the circuit layer formed using the plating layer. Furthermore, it is difficult to achieve fine pitch circuits using the electrical connection structure of electronic components (elements), and also an RDL (ReDistributed Layer) process for electrically connecting electronic components (elements) should be additionally performed, undesirably complicating the manufacturing process.

### SUMMARY OF THE INVENTION

Accordingly, the present invention has been made keeping in mind the problems encountered in the related art and the present invention is intended to provide a PCB having an embedded electronic component and a method of manufacturing the same, in which metal bumps formed on an electronic component are directly connected to a circuit layer, thus increasing reliability of the electrical connection, and also in which a polymer layer is used so that the force of adhesion to a plating layer is ensured, thus increasing reliability of a circuit layer formed using the plating layer.

An aspect of the present invention provides a PCB having an embedded electronic component, comprising a metal bump for electrically connecting the electronic component embedded in the printed circuit board, wherein the metal bump is formed so as to be directly connected with a circuit layer of the printed circuit board.

Another aspect of the present invention provides a PCB having an embedded electronic component, comprising a first insulating layer, an electronic component disposed in an opening formed in a thickness direction of the first insulating layer and having a metal bump, a polymer layer formed on one side of the first insulating layer and on which the electronic component is seated so that the metal bump of the electronic component perforates the polymer layer, a second insulating layer formed on the other side of the first insulating layer so as to embed the electronic component, a first circuit layer formed on the second insulating layer, and a second circuit layer formed on the polymer layer so as to be directly electrically connected to the metal bump that perforates the polymer layer.

In this aspect, the polymer layer may have roughness on a side on which the second circuit layer is formed.

In this aspect, the polymer layer may comprise a copper foil layer and a polyimide (PI) film or an Ajinomoto build-up film (ABF) applied thereon.

In this aspect, the first insulating layer may be completely cured.

In this aspect, the second insulating layer may be semi-cured.

A further aspect of the present invention provides a method of manufacturing a PCB having an embedded electronic component, comprising preparing a polymer layer, seating an electronic component having a metal bump that perforates the polymer layer on one side of the polymer layer, forming a first insulating layer having an opening on the one side of the polymer layer, forming a second insulating layer on one side of the first insulating layer having the opening, and forming a first circuit layer and a second circuit layer on the second insulating layer and the polymer layer, wherein the second circuit layer formed on the polymer layer is directly electrically connected with the metal bump that perforates the polymer layer.

In this aspect, the polymer layer may have roughness on a side on which the second circuit layer is formed.

In this aspect, the polymer layer may comprise a copper foil layer and a PI film or ABF applied thereon.

In this aspect, the first insulating layer may be completely cured.

In this aspect, the second insulating layer may be semi-cured.

In this aspect, in preparing the polymer layer, the polymer layer may be provided in a form which has a carrier member attached thereto, and the method may further comprise removing the carrier member after forming the second insulating layer on one side of the first insulating layer having the opening.

Still a further aspect of the present invention provides a method of manufacturing a PCB having an embedded electronic component, comprising preparing a polymer layer, forming a first insulating layer having an opening on one side of the polymer layer, seating in the opening an electronic component having a metal bump that perforates the polymer layer, forming a second insulating layer on one side of the first insulating layer having the opening, and forming a first circuit layer and a second circuit layer on the second insulating layer and the polymer layer, wherein the second circuit layer formed on the polymer layer is directly electrically connected with the metal bump that perforates the polymer layer.

In this aspect, the polymer layer may have roughness on a side on which the second circuit layer is formed.

In this aspect, the polymer layer may comprise a copper foil layer and a PI film or ABF applied thereon.

In this aspect, the first insulating layer may be completely cured.

In this aspect, the second insulating layer may be semi-cured.

In this aspect, in preparing the polymer layer, the polymer layer may be provided in a form which has a carrier member attached thereto, and the method may further comprise removing the carrier member after forming the second insulating layer on one side of the first insulating layer having the opening.

### BRIEF DESCRIPTION OF THE DRAWINGS

The features and advantages of the present invention will be more clearly understood from the following detailed description taken in conjunction with the accompanying drawings, in which:

FIG. 1 is a cross-sectional view showing a PCB according to the present invention;

FIGS. 2 to 8 are views showing a process of manufacturing a PCB according to a first embodiment of the present invention; and

FIGS. 9 to 16 are views showing a process of manufacturing a PCB according to a second embodiment of the present invention.

### DESCRIPTION OF SPECIFIC EMBODIMENTS

Hereinafter, embodiments of the present invention will be described in detail while referring to the accompanying drawings. Throughout the drawings, the same reference numerals are used to refer to the same or similar elements. In the description, the terms “one side”, “the other side”, “first”, “second” and so on are used to distinguish one element from another element and not to define the elements. Moreover, descriptions of known techniques, even if they are pertinent to the present invention, are regarded as unnecessary and may be omitted when they would make the characteristics of the invention and the description unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

FIG. 1 is a cross-sectional view showing a PCB according to the present invention. According to the present invention, the PCB having an embedded electronic component includes metal bumps 32 formed on one side of an electronic component 31 that was embedded in the PCB in order to achieve electrical connection of the electronic component 31, the metal bumps 32 being directly connected with a circuit layer of the PCB. According to an embodiment, the PCB having an embedded electronic component comprising the metal bumps 32 includes a first insulating layer 41, an electronic component 31 disposed in an opening formed in a thickness direction of the first insulating layer 41 and having the metal bumps 32, a polymer layer 20 formed on one side of the first insulating layer 41 and through which the metal bumps 32 of the electronic component 31 are perforated and on which the electronic component 31 is seated, a second insulating layer 42 formed on the other side of the first insulating layer 41 so as to embed the electronic component 31, a first circuit layer 51 formed on the second insulating layer 42, and a second circuit layer 61 formed on the polymer layer 20 so as to be directly electrically connected to the metal bumps 32 that perforate the polymer layer 20.

The first insulating layer 41 functions as an insulating substrate, and includes the opening formed in its thickness direction so that the electronic component 31 can be mounted. The first insulating layer 41 may be formed of an insulating material having low fluidity, and one which is completely cured may be used for the first insulating layer 41. Processing the opening of the first insulating layer may take into consideration the size of the electronic component 31. When the electronic component 31 is mounted in the opening, the opening is filled with an insulating material having high fluidity, whereby the electronic component 31 is fixed. The electronic component 31 is mounted in such a way that an active element is mounted in a face-up or face-down manner. The metal bumps 32 are formed on the electronic component 31 in order to achieve an electrical connection. The metal bumps 32 may be bumps made of copper (Cu), but the present invention is not necessarily limited thereto. Any metal material may be used for the metal bumps 32 as long as it is conductive and may be formed on the electronic component 31.

The polymer layer 20 is formed on one side of the first insulating layer 41, and the electronic component 31 is seated thereon. The polymer layer 20 is made of an insulating material and may have roughness in order to ensure peel strength between it and a plating layer in the course of subsequently forming the second circuit layer 61. In the case where the electronic component 31 is seated on the polymer layer 20, the metal bumps 32 formed on the electronic component 31 are formed so as to perforate the polymer layer 20. By means of these metal bumps 32 that perforate the polymer layer 20, the second circuit layer 61 and the electronic component 31 formed on both sides of the polymer layer 20 may be directly connected with each other. Thus, compared to conventional cases, an increase in the reliability of electrical connection of the electronic component 31 may be achieved. The polymer layer 20 comprises a copper foil layer and a polyimide (PI) film or an Ajinomoto build-up film (ABF) having good plating adhesion applied thereon. As the peel strength between the polymer layer 20 and the second metal layer 60 is ensured, a fine circuit pattern may result. Even when the fine circuit pattern is formed, the reliability of electrical connection may be maintained, and thus operative performance of the PCB may be further increased.

The second insulating layer 42 is formed on one side of the first insulating layer 41, and functions to embed and fix the electronic component 31 disposed in the opening of the first insulating layer 41. Thus, an insulating material having higher fluidity than that of the first insulating layer 41 is used. Particularly useful is a semi-cured insulating material.

The first circuit layer 51 is formed on the second insulating layer 42. The first circuit layer 51 may be formed by subjecting a first metal layer 50 which is not shown in the drawing to a subtractive process or an additive process. For example, according to the subtractive process, applying an etching resist on the first metal layer 50 to form a circuit pattern, etching the first metal layer 50 having the etching resist applied thereon, and removing the etching resist are performed, thus forming the first circuit layer 51. In the case where a seed layer is provided to form the first metal layer 50, selectively etching the exposed seed layer may be additionally performed after removing the etching resist. The method of forming the first circuit layer 51 is not necessarily limited thereto, and other circuit formation methods may be used. Alternatively, upon formation of a multilayered PCB including a build-up insulating layer and a build-up circuit layer, the circuit layers including vias for making electrical connections may be formed.

The second circuit layer 61 is formed on the polymer layer 20. The circuit pattern may result from forming the second metal layer 60 on the polymer layer 20. The method of forming the second circuit layer 61 is the same as the method of forming the first circuit layer 51 and thus its description is omitted. Because the second circuit layer 61 is formed on the polymer layer 20, the polymer layer 20 has roughness to thus ensure the peel strength between the polymer layer and the second metal layer 60, thereby obtaining the force of adhesion between it and the second circuit layer 61. As the peel strength between the second circuit layer 61 and the polymer layer 20 is enhanced, reliability of the electrical connection may be maintained even when forming the fine circuit pattern. Furthermore, there is no need for an additional RDL process for changing the position of pads acting as input-output terminals of the electronic component 31. Also upon formation of a multilayered PCB including a build-up insulating layer and a build-up circuit layer, the circuit layers including vias for making electrical connections may be formed.

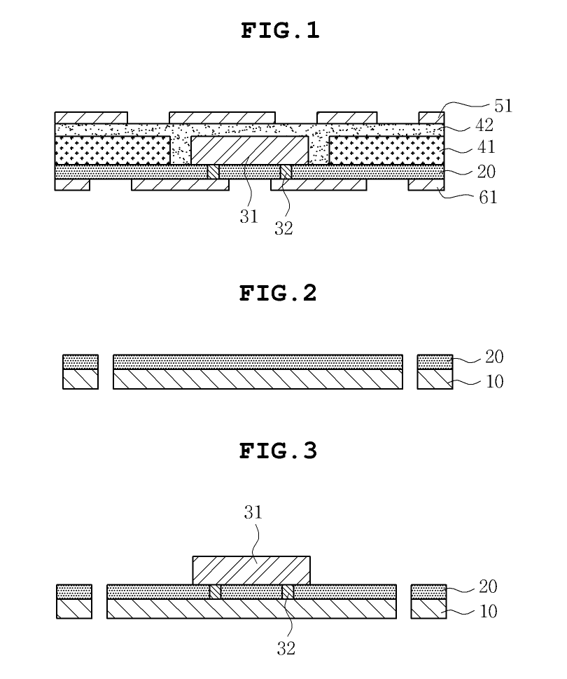

FIGS. 2 to 8 show a process of manufacturing a PCB according to a first embodiment of the present invention. The method of manufacturing the PCB having an embedded electronic component according to the first embodiment of the present invention includes preparing a polymer layer 20, seating an electronic component 31 having metal bumps 32 that perforate the polymer layer 20 on one side of the polymer layer 20, forming a first insulating layer 41 having an opening on one side of the polymer layer 20, forming a second insulating layer 42 on one side of the first insulating layer 41 having the opening, and respectively forming a first circuit layer 51 and a second circuit layer 61 on the second insulating layer 42 and the polymer layer 20, in which the second circuit layer 61 formed on the polymer layer 20 is directly electrically connected with the metal bumps 32 that perforate the polymer layer 20.

In order to protect the roughness for supplementing the supporting force of the polymer layer 20 and ensuring the peel strength upon plating of a metal layer, a carrier member may be further formed on the polymer layer 20. Specifically, upon preparing the polymer layer 20, the polymer layer 20 may be provided in the form of the carrier member 10 having been attached thereto, and the carrier member may be removed after forming the second insulating layer 42 on one side of the first insulating layer 41 having the opening.

Below, the method of manufacturing the PCB having an embedded electronic component including attaching the carrier member 10 to the polymer layer 20 is specified.

FIG. 2 shows forming the polymer layer 20 on the carrier member 10. The electronic component 31 may be directly seated on the polymer layer 20 thus manufacturing a PCB having an embedded electronic component, and in order to supplement the supporting force of the polymer layer 20, the manufacturing process of the PCB may be performed using the carrier member 10. As such, the carrier member 10 is separated and removed during the subsequent PCB manufacturing process. The carrier member 10 is not particularly limited, and the PCB manufacturing process may be initiated using a typical carrier member 10. The typical carrier member 10 may be obtained by forming adhesive films on both sides of a copper clad laminate (CCL) and then sequentially forming metal layers on respective sides thereof.

FIG. 3 shows seating the electronic component 31 on the polymer layer 20. This process is performed so that the metal bumps 32 formed on the electronic component 31 perforate the polymer layer 20 and are thus seated thereon. As the metal bumps 32 perforate the polymer layer 20, it is easy to electrically connect them with the second circuit layer 61 which is subsequently formed on the polymer layer 20. The metal bumps 32 may be made of a conductive metal. For example, Cu bumps may be provided, and the metal bumps 32 may be formed using a variety of other conductive materials. The electronic component 31 may be mounted in such a way that an active element is mounted in a face-up or face-down manner. Because the metal bumps 32 of the electronic component 31 perforate the polymer layer 20 and are thus directly connected with the circuit layer, the polymer layer 20 may be formed so as to correspond to the position of the metal bumps 32 of the electronic component 31.

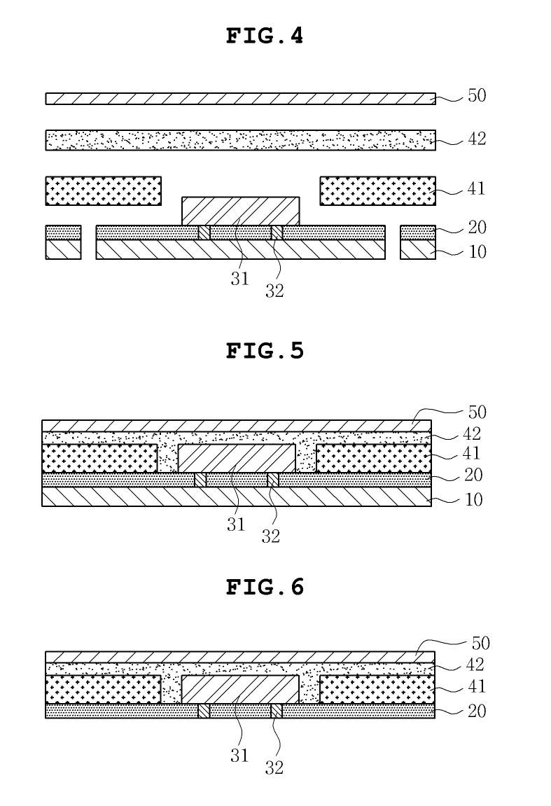

FIG. 4 shows forming the first insulating layer 41 having the opening for mounting the electronic component 31 on the polymer layer 20, forming the second insulating layer 42 on one side of the first insulating layer 41 having the opening, and forming the first metal layer 50. FIG. 5 is a cross-sectional view showing the PCB according to FIG. 4. As seen in FIG. 4, the first insulating layer 41 may be formed using a prepreg or unclad (a prepreg in a C stage) so as to correspond to the thickness of the electronic component 31. After forming the first insulating layer 41, the second insulating layer 42 is formed in order to embed and fix the electronic component 31. The second insulating layer 42 is formed to cover the opening in which the electronic component 31 is disposed. Unlike the first insulating layer 41, an insulating material having high fluidity may be used in order to embed the electronic component 31. A prepreg in a semi-cured state or another insulating material may be used. Any insulating material may be used for the second insulating layer 42 so long as it has fluidity so that the electronic component 31 can be embedded therein. The second insulating layer 42 may be formed using a material which is cured to a lesser degree than the first insulating layer 41, and an insulating material which is semi-cured may be used. After the electronic component 31 is fixed by providing the second insulating layer 42, the first metal layer 50 is formed. Although the first metal layer 50 is not specifically shown in the drawing, it may be formed using a seed layer which plays a role as an electrical lead wire. The first metal layer 50 may then be subjected to a subtractive process or an additive process, thus forming the first circuit layer 51.

FIG. 6 shows removing the carrier member 10. In order to initiate the PCB manufacturing process by forming the polymer layer 20, the polymer layer 20 is provided in the form of having been attached to the carrier member 10. After removal of the carrier member 10, the second circuit layer 61 is formed on the polymer layer 20 thus manufacturing the PCB. The side of the polymer layer 20 from which the carrier member 10 was removed has roughness, whereby the peel strength between the polymer layer and the second metal layer 60 may be enhanced thus enabling the formation of the fine circuit pattern. The polymer layer 20 resulting from coating a CCL with a PI film or ABF having good plating adhesion may be used. Thus, a fine circuit pattern may be formed thanks to the use of the polymer layer 20, and reliability of the electrical connection may also be maintained, thus further improving the operative performance of the PCB.

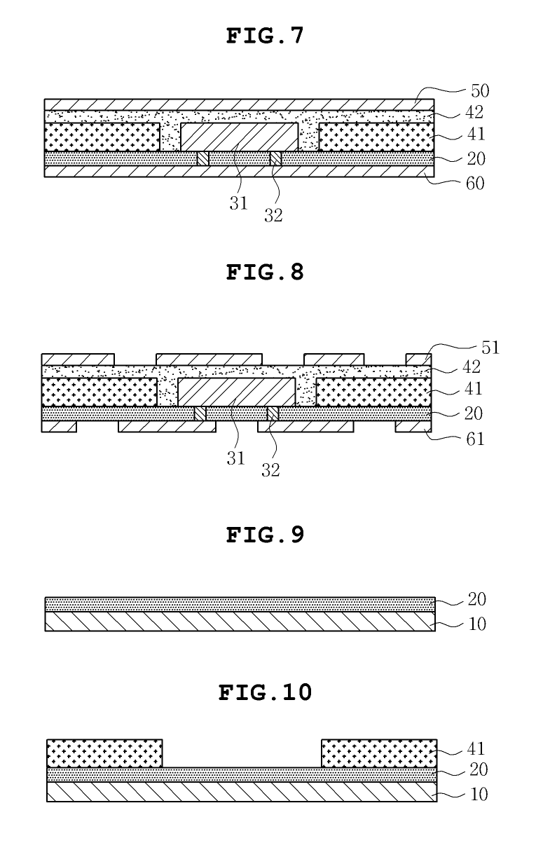

FIG. 7 shows forming the second metal layer 60 on the polymer layer 20 from which the carrier member 10 was removed. As mentioned above, because the polymer layer 20 has roughness, the peel strength between it and the second metal layer 60 may be enhanced. The second metal layer 60 may be formed by forming a seed layer functioning as an electrical lead wire which is not shown in the drawing and then performing electroplating. Alternatively, the second metal layer 60 may be formed using other processes.

FIG. 8 shows forming the first circuit layer 51 and the second circuit layer 61. The first circuit layer 51 is formed on the second insulating layer 42. The first circuit layer 51 may be formed by subjecting the first metal layer 50 which is not shown in the drawing to a subtractive process or an additive process. The specified description of forming the first circuit layer 51 and the second circuit layer 61 overlaps with the aforementioned description and is thus omitted.

FIGS. 9 to 16 show a process of manufacturing a PCB having an embedded electronic component according to a second embodiment of the present invention. The method of manufacturing the PCB having an embedded electronic component according to the second embodiment of the present invention includes preparing a polymer layer, forming a first insulating layer having an opening on one side of the polymer layer, seating an electronic component having metal bumps that perforate the polymer layer in the opening, forming a second insulating layer on one side of the first insulating layer having the opening, and forming a first circuit layer and a second circuit layer on the second insulating layer and the polymer layer, in which the second circuit layer formed on the polymer layer is directly electrically connected with the metal bumps that perforate the polymer layer.

In order to protect the roughness for supplementing the supporting force of the polymer layer 20 and ensuring the peel strength upon plating of a metal layer, a carrier member may be formed on the polymer layer 20. Specifically, upon preparing the polymer layer, the polymer layer may be provided in the form of the carrier member having been attached thereto, and the carrier member may be removed after forming the second insulating layer on one side of the first insulating layer having the opening. Below, the PCB manufacturing process including attaching the carrier member 10 to the polymer layer 20 according to the second embodiment is described.

Below, the description that overlaps with the description of the method of manufacturing the PCB having an embedded electronic component according to the first embodiment is omitted.

FIG. 9 shows forming the polymer layer 20 on the carrier member 10, and FIG. 10 shows forming the first insulating layer 41 having the opening for mounting the electronic component 31. The electronic component 31 may be directly seated on the polymer layer 20 thus manufacturing a PCB having an embedded electronic component. The PCB manufacturing process may be conducted using the carrier member 10 for supplementing the supporting force of the polymer layer 20. As such, the carrier member 10 is separated and removed during the subsequent PCB manufacturing process. Whereas the electronic component 31 is seated on the polymer layer 20 and then the first insulating layer 41 having the opening is formed thereon so that the electronic component 31 is disposed in the opening in the first embodiment, the first insulating layer 41 having the opening for mounting the electronic component 31 is first formed in the present embodiment. Thus, the first insulating layer 41 has the opening for mounting the electronic component 31 and may be formed in a way that corresponds to the thickness of the electronic component 31.

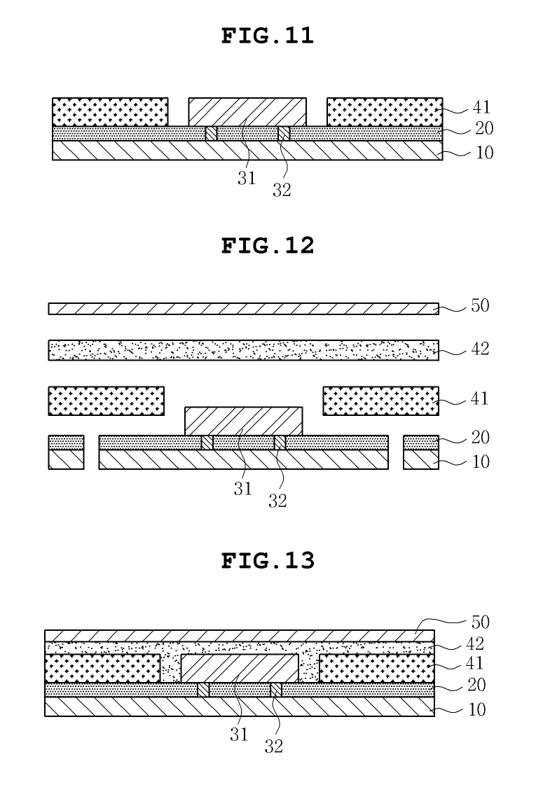

FIG. 11 shows disposing the electronic component 31 having the metal bumps 32 in the opening of the first insulating layer 41. The electronic component 31 may be seated on the polymer layer 20 so that the metal bumps 32 perforate the polymer layer 20. As the metal bumps 32 of the electronic component 31 are formed so as to perforate the polymer layer 20, a direct electrical connection between the electronic component 31 and the second circuit layer 61 which is subsequently formed on the polymer layer 20 may be achieved. When the metal bumps 32 of the electronic component 31 are directly electrically connected with the second circuit layer 61, it is possible to accomplish fine pitch circuits.

FIG. 12 shows forming the second insulating layer 42 on the first insulating layer 41 so as to embed and fix the electronic component 31 seated in the opening, and forming the first metal layer 50 on the second insulating layer 42, after forming the first insulating layer 41 having the opening on the polymer layer 20. FIG. 13 is a cross-sectional view showing the PCB according to FIG. 12. The specified description thereof overlaps with the descriptions of FIGS. 4 and 5 in the PCB manufacturing process according to the first embodiment and thus is omitted.

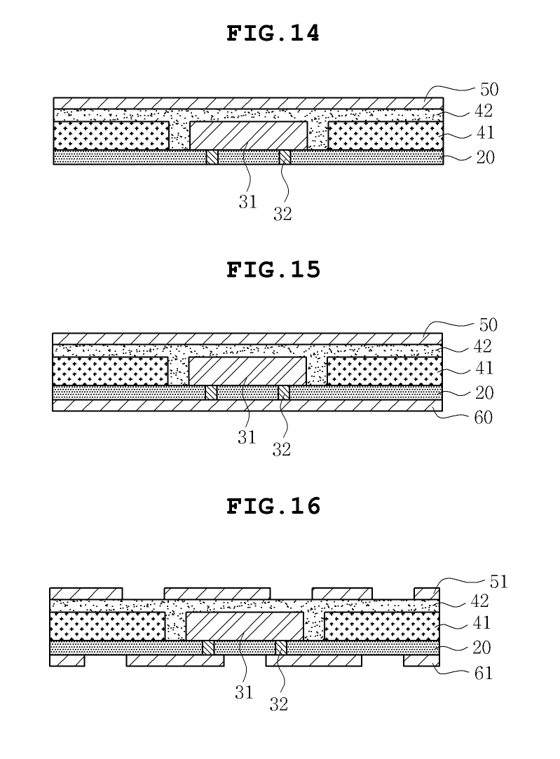

FIG. 14 shows removing the carrier member 10. In order to initiate the PCB manufacturing process by forming the polymer layer 20, the polymer layer 20 is provided in the form of having been attached to the carrier member 10. After removal of the carrier member 10, the second circuit layer 61 is formed on the polymer layer 20 thus manufacturing the PCB. This description overlaps with that of FIG. 6 in the PCB manufacturing process according to the first embodiment and is thus omitted.

FIG. 15 shows forming the second metal layer 60 on the polymer layer 20 from which the carrier member 10 was removed. As mentioned above, the polymer layer 20 has roughness, and thereby the peel strength between it and the second metal layer 60 may be enhanced. The second metal layer 60 may be formed by forming a seed layer which is not shown in the drawing functioning as an electrical lead wire and then performing electroplating. In addition, the second metal layer 60 may be formed using other processes.

FIG. 16 shows forming the first circuit layer 51 and the second circuit layer 61. The first circuit layer 51 is formed on the second insulating layer 42. The first metal layer 50 which is not shown in the drawing may be subjected to a subtractive process or an additive process, resulting in a circuit layer having a via. The specified description for forming the first circuit layer 51 and the second circuit layer 61 overlaps with the aforementioned description and is thus omitted.

As described hereinbefore, the present invention provides a PCB having an embedded electronic component and a method of manufacturing the same. According to the present invention, there is no need to process a via for electrically connecting electronic components, thus reducing the processing cost and simplifying the manufacturing process.

Also, a polymer layer has roughness so as to enhance the force of adhesion thereof to a plating layer, thus ensuring reliability of the electrical connection of a circuit layer which is subsequently formed.

Also, metal bumps of the electronic component are formed so that they perforate the polymer layer, thus achieving a direct electrical connection with the circuit layer, resulting in fine pitch circuits.

Also, there is no need to perform an additional RDL process for changing the position of pads functioning as input-output terminals of the electronic component.

Although the embodiments of the present invention regarding the PCB having an embedded electronic component therein and the method of manufacturing the same have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A printed circuit board having an embedded electronic component, comprising a metal bump for electrically connecting the electronic component embedded in the printed circuit board, wherein the metal bump is formed so as to be directly connected with a circuit layer of the printed circuit board.

2. A printed circuit board having an embedded electronic component, comprising:
a first insulating layer;
an electronic component disposed in an opening formed in a thickness direction of the first insulating layer and having a metal bump;
a polymer layer formed on one side of the first insulating layer and on which the electronic component is seated so that the metal bump of the electronic component perforates the polymer layer;
a second insulating layer formed on the other side of the first insulating layer so as to embed the electronic component;
a first circuit layer formed on the second insulating layer; and
a second circuit layer formed on the polymer layer so as to be directly electrically connected to the metal bump that perforates the polymer layer.

3. The printed circuit board of claim 2, wherein the polymer layer has roughness on a side on which the second circuit layer is formed.

4. The printed circuit board of claim 2, wherein the polymer layer comprises a copper foil layer and a polyimide (PI) film or an Ajinomoto build-up film (ABF) applied thereon.

5. The printed circuit board of claim 2, wherein the first insulating layer is completely cured.

6. The printed circuit board of claim 2, wherein the second insulating layer is semi-cured.

7. A method of manufacturing a printed circuit board having an embedded electronic component, comprising:
preparing a polymer layer;
seating an electronic component having a metal bump that perforates the polymer layer on one side of the polymer layer;
forming a first insulating layer having an opening on the one side of the polymer layer;
forming a second insulating layer on one side of the first insulating layer having the opening; and
forming a first circuit layer and a second circuit layer on the second insulating layer and the polymer layer, wherein the second circuit layer formed on the polymer layer is directly electrically connected with the metal bump that perforates the polymer layer.

8. The method of claim 7, wherein the polymer layer has roughness on a side on which the second circuit layer is formed.

9. The method of claim 7, wherein the polymer layer comprises a copper foil layer and a polyimide (PI) film or an Ajinomoto build-up film (ABF) applied thereon.

10. The method of claim 7, wherein the first insulating layer is completely cured.

11. The method of claim 7, wherein the second insulating layer is semi-cured.

12. The method of claim 7, wherein in preparing the polymer layer, the polymer layer is provided in a form which has a carrier member attached thereto, and the method further comprises removing the carrier member after forming the second insulating layer on one side of the first insulating layer having the opening.

13. A method of manufacturing a printed circuit board having an embedded electronic component, comprising:
preparing a polymer layer;
forming a first insulating layer having an opening on one side of the polymer layer;
seating in the opening an electronic component having a metal bump that perforates the polymer layer;
forming a second insulating layer on one side of the first insulating layer having the opening; and
forming a first circuit layer and a second circuit layer on the second insulating layer and the polymer layer, wherein the second circuit layer formed on the polymer layer is directly electrically connected with the metal bump that perforates the polymer layer.

14. The method of claim 13, wherein the polymer layer has roughness on a side on which the second circuit layer is formed.

15. The method of claim 13, wherein the polymer layer comprises a copper foil layer and a polyimide (PI) film or an Ajinomoto build-up film (ABF) applied thereon.

16. The method of claim 13, wherein the first insulating layer is completely cured.

17. The method of claim 13, wherein the second insulating layer is semi-cured.

18. The method of claim 13, wherein in preparing the polymer layer, the polymer layer is provided in a form which has a carrier member attached thereto, and the method further comprises removing the carrier member after forming the second insulating layer on the one side of the first insulating layer having the opening.
